(19) United States
(12) Patent Application Publication
(10) Pub. No.: US 2021/0223507 A1
(43) Pub. Date: Jul. 22, 2021

(54) LIGHT EMISSION APPARATUS FOR EXPOSURE MACHINE AND EXPOSURE EQUIPMENT INCLUDING SAME

(71) Applicant: POINT ENGINEERING CO., LTD., Asan (KR)

(72) Inventors: Bum Mo AHN, Suwon (KR); Young Heum EOM, Anyang (KR); Sin Seok HAN, Hwaseong (KR)

(21) Appl. No.: 17/153,433

(22) Filed: Jan. 20, 2021

(30) Foreign Application Priority Data
Jan. 20, 2020 (KR) 10-2020-0007584

(51) Int. Cl. G02B 7/182; G03F 7/20; G02B 5/10; G02B 5/00; G02B 27/30

(52) U.S. Cl. CPC G02B 7/182; G03F 7/7005; G02B 27/30; G02B 5/005; G02B 5/10

(57) ABSTRACT

Light emission apparatus for an exposure machine is proposed. The light emission apparatus includes: a supporter; a plurality of light emission units individually installed on a first surface of the supporter and each having a plurality of light emitters generating light; and a plurality of reflectors individually installed on the first surface of the supporter to correspond to the light emission units, respectively, in which the reflectors are divided into a first reflective group in which reference axes of reflective beams are horizontal and a second reflective group in which reference axes of reflective beams are inclined.

### CROSS REFERENCE TO RELATED APPLICATION

The present application claims priority to Korean Patent Application No. 10-2020-0007584, filed Jan. 20, 2020, the entire contents of which is incorporated herein for all purposes by this reference.

### BACKGROUND OF THE INVENTION

### Field of the Invention

The present disclosure relates to a light emission apparatus for an exposure machine and exposure equipment including same and, particularly, to a light emission apparatus for an exposure machine, that light emission apparatus being used to manufacture a semiconductor device, a printed circuit board, a liquid crystal display panel, etc., using a plurality of LED, and exposure equipment including the light emission apparatus.

### Description of the Related Art

In the related art, large high-voltage mercury lamps of several kW to tens of kW were mostly used as light sources for exposing a printed circuit board, a liquid crystal display panel, etc. Light sources using a high-voltage mercury lamp for an exposure machine have been used for a long time.

However, there is a problem that light sources using a high-voltage mercury lamp for an exposure machine have a short lifespan, consume a great amount of power, take long time to preheat the lamp, generate a loss because exposure is impossible while the light sources are replaced when the light sources are damaged, require a large cooling equipment for high temperature, need to be increased in size to increase the amount and illumination of light that reaches an irradiation region, and cannot turn on/off the lamp even though exposure is not required.

Recently, a light emission apparatus for an exposure machine that uses a light emitting diode (LED) as a new light source was developed to replace the high-voltage mercury lamp of the related art. A light emitting diode has high light emission efficiency, consumes a small amount of power, and generates a small amount of heat in comparison to the mercury lamp, so the cost for maintenance can be reduced. Further, since the life span of a light emitting diode is long in comparison to the mercury lamp, the cost for replacement can be reduced and there is no possibility of breaking due to deterioration, etc.

However, in Patent Document 1, a light source for an exposure machine was configured by two-dimensionally arranging a plurality of LEDs on a plate member, but it is required to arrange a large number of LEDs on a two-dimensional plane to achieve a sufficient amount of light and it is required to necessarily maintain a predetermined distance or more between the light sources for an exposure machine and a beam uniformer. Accordingly, there is a problem that the size of exposure equipment is increased.

### DOCUMENTS OF RELATED ART

(Patent Document 1) Japanese Patent Application Publication No. 2004-335952 (Nov. 25, 2004)

### SUMMARY OF THE INVENTION

A light emission apparatus for an exposure machine according to an embodiment of the present disclosure and exposure equipment including the light emission apparatus can be manufactured in a small size because the light emission apparatus for an exposure machine and a beam uniformer 30 can be disposed within a predetermined distance from each other.

The light emission apparatus for an exposure machine according to an embodiment of the present disclosure and exposure equipment including the light emission apparatus can obtain a sufficient amount of light and can be decreased in size in up, down, left, and right directions because a plurality of light emitters is three-dimensionally arranged.

The light emission apparatus for an exposure machine according to an embodiment of the present disclosure and exposure equipment including the light emission apparatus can provide parallel beams that are perpendicular to an irradiation region by having a reflective surface corresponding to a plurality of light emitters three-dimensionally arranged.

The light emission apparatus for an exposure machine according to an embodiment of the present disclosure and exposure equipment including the light emission apparatus can minimize light that is lost as dead light that does not reach an irradiation region.

The light emission apparatus for an exposure machine according to an embodiment of the present disclosure and exposure equipment including the light emission apparatus can minimize a shade section, which may be generated in an irradiation region, and can have uniform illumination.

An embodiment of the present disclosure may provide a light emission apparatus for an exposure machine and exposure equipment including the light emission apparatus. The light emission apparatus includes: a supporter; a plurality of light emission units individually installed on a first surface of the supporter and each having a plurality of light emitters generating light; and a plurality of reflectors individually installed on the first surface of the supporter to correspond to the light emission units, respectively, in which the reflectors are divided into a first reflective group in which reference axes of reflective beams are inclined and a second reflective group in which reference axes of reflective beams are horizontal.

In the light emission apparatus for an exposure machine according to an embodiment of the present disclosure and exposure equipment including the light emission apparatus, the first reflective group may be positioned further outside a center portion on the first surface of the supporter than the second reflective group.

In the light emission apparatus for an exposure machine according to an embodiment of the present disclosure and exposure equipment including the light emission apparatus, the direction of the reference axis of a reflective beam may be an average of directions of optical axes of reflective beams reflected by one reflector.

In the light emission apparatus for an exposure machine according to an embodiment of the present disclosure and exposure equipment including the light emission apparatus, the light emission units and the reflectors each may be individually detachably coupled to the supporter.

In the light emission apparatus for an exposure machine according to an embodiment of the present disclosure and exposure equipment including the light emission apparatus, the reflectors each may have: a plurality of reflective surfaces reflecting light in correspondence to each of the light emitters installed on one of the light emission units; and a reflector body integrally or detachably having the reflective surfaces.

In the light emission apparatus for an exposure machine according to an embodiment of the present disclosure and exposure equipment including the light emission apparatus, the reflective surfaces may be at least one of parabolic surfaces, elliptical surfaces, or free curve surfaces.

In the light emission apparatus for an exposure machine according to an embodiment of the present disclosure and exposure equipment including the light emission apparatus, the supporter itself may be a water-cooling member or the supporter may be cooled by a supporter cooler attached to a rear surface of the supporter.

The exposure equipment including the light emission apparatus according to an embodiment of the present disclosure includes: a light emission apparatus generating beams; an aperture removing unnecessary beams from the beams; a beam uniformer uniforming the beams; at least one mirror making beams that have passed through the beam uniformer into parallel beams; a mask stage supporting a mask that transmits the parallel beams; and an object stage supporting an object to which beams that have passed through the mask reach, in which the light emission apparatus includes: a supporter; a plurality of light emission units individually installed on a first surface of the supporter and each having a plurality of light emitters generating light on an outer surface thereof; and a plurality of reflectors individually installed on the first surface of the supporter to correspond to the light emission units, respectively, in which the reflectors are divided into a first reflective group in which reference axes of reflective beams are inclined and a second reflective group in which reference axes of reflective beams are horizontal.

A light radiation apparatus for an exposure machine according to an embodiment of the present disclosure and exposure equipment including the light radiation apparatus can be manufactured in a small size because the light radiation apparatus for an exposure machine and a beam uniformer can be disposed within a predetermined distance from each other.

The light emission apparatus for an exposure machine according to an embodiment of the present disclosure and exposure equipment including the light emission apparatus can obtain a sufficient amount of light and can be decreased in size in up, down, left, and right directions because a plurality of light emitters is three-dimensionally arranged.

The light emission apparatus for an exposure machine according to an embodiment of the present disclosure and exposure equipment including the light emission apparatus can provide parallel beams that are perpendicular to an irradiation region by having a reflective surface corresponding to a plurality of light emitters three-dimensionally arranged.

The light emission apparatus for an exposure machine according to an embodiment of the present disclosure and exposure equipment including the light emission apparatus can minimize light that is lost as dead light that does not reach an irradiation region.

The light emission apparatus for an exposure machine according to an embodiment of the present disclosure and exposure equipment including the light emission apparatus can minimize a shade section, which may be generated in an irradiation region, and can have uniform illumination.

### BRIEF DESCRIPTION OF THE DRAWINGS

The above and other objectives, features and other advantages of the present invention will be more clearly understood from the following detailed description when taken in conjunction with the accompanying drawings, in which:

FIG. 1A is a schematic perspective view of a light emission apparatus 10 for an exposure machine according to an embodiment of the present disclosure;

FIG. 1B is a front view of the light emission apparatus 10 for an exposure machine according to an embodiment of the present disclosure;

FIG. 2A is a cross-sectional view of the light emission apparatus 10 according to an embodiment of the present disclosure and FIG. 2B is a cross-sectional view of a light emission apparatus 10 according to another embodiment of the present disclosure;

FIGS. 3A, 3B, and 3C are a cross-sectional view, an exploded perspective view, and a front view of a reflector 500 according to an embodiment;

FIGS. 4A and 4B are a cross-sectional view and a plan view of a reflector 500 according to another embodiment;

FIGS. 5A and 5B are cross-sectional views of a reflector according to another embodiment;

FIGS. 6A, 6B, and 6C are cross-sectional views of a reflector according to another embodiment;

FIG. 7A is a perspective view of a light emission unit, FIG. 7B is a rear view of the light emission unit 300 seen from the rear, FIG. 7C is a view showing the structure in which a first supporter fixer 110 of a supporter 100 is formed in a hole shape, and FIG. 7D is a cross-sectional view in which the light emission unit 300 is coupled to the first supporter fixer 110 of the supporter 100;

FIG. 8A is a front view of the supporter and FIG. 8B is a rear view of the supporter;

FIG. 9A is a view showing beam profiles of a plurality of light emitters installed on one installation surface, FIG. 9B is a view showing the optical axes of a plurality of light emitters installed on one installation surface, FIG. 9C is a view showing the distances between a plurality of light emitters installed on one installation surface, and FIG. 9D is a view showing the number of a plurality of light emitters installed on one installation surface; and

FIG. 10 is a view showing the configuration of exposure equipment 1 using the light emission apparatus 10 for an exposure machine.

### DETAILED DESCRIPTION OF THE INVENTION

The description of specific structures and functions of embodiments according to the concept of the present disclosure described herein are provided as examples for describing the embodiments according to the concept of the present disclosure. The embodiments according to the spirit of the present disclosure may be implemented in various ways and the present disclosure is not limited to the embodiments described herein.

Embodiments described herein may be changed in various ways and various shapes, so specific embodiments are shown in the drawings and will be described in detail in this specification. However, it should be understood that the exemplary embodiments according to the concept of the present disclosure are not limited to the specific examples, but all of modifications, equivalents, and substitutions are included in the scope and spirit of the present disclosure.

It will be understood that, although the terms first, second, etc. may be used herein to describe various elements, these elements should not be limited by these terms. These terms are only used to distinguish one element, from another element. For instance, a first element discussed below could be termed a second element without departing from the right range of the present disclosure. Similarly, the second element could also be termed the first element.

It is to be understood that when one element is referred to as being “connected to” or “coupled to” another element, it may be connected directly to or coupled directly to another element or be connected to or coupled to another element, having the other element intervening therebetween. On the other hand, it should to be understood that when one element is referred to as being “connected directly to” or “coupled directly to” another element, it may be connected to or coupled to another element without the other element intervening therebetween. Meanwhile, the terms used herein to describe a relationship between elements, that is, “between”, “directly between”, “adjacent” or “directly adjacent” should be interpreted in the same manner as those described above.

Technological terms used in the specification are used only in order to describe specific exemplary embodiments rather than limiting the present disclosure. Singular forms are intended to include plural forms unless the context clearly indicates otherwise. It will be further understood that the terms “comprises” or “have” used in this specification, specify the presence of stated features, numbers, steps, operations, components, parts, or a combination thereof, but do not preclude the presence or addition of one or more other features, numerals, steps, operations, components, parts, or a combination thereof.

A light emission apparatus for an exposure machine and exposure equipment 100 including the light emission apparatus according to an embodiment of the present disclosure are described hereafter with reference to the drawings.

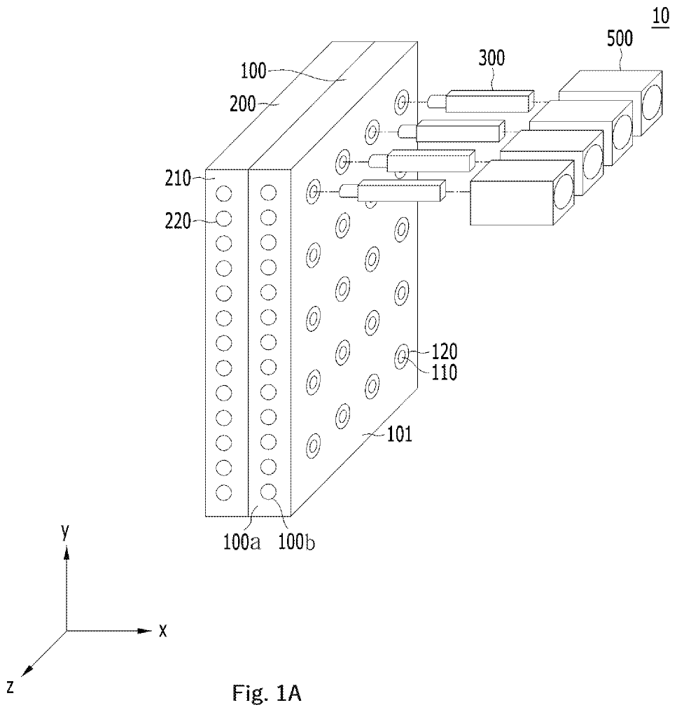

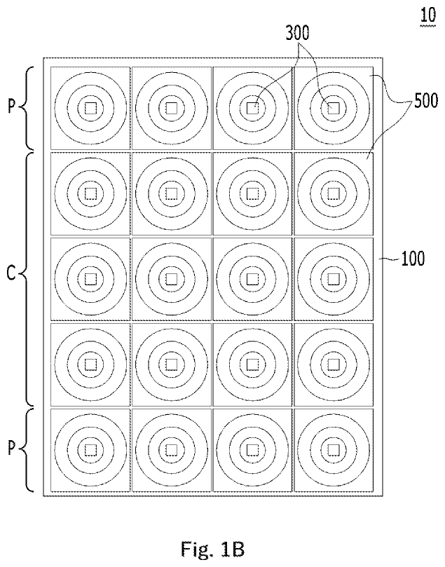

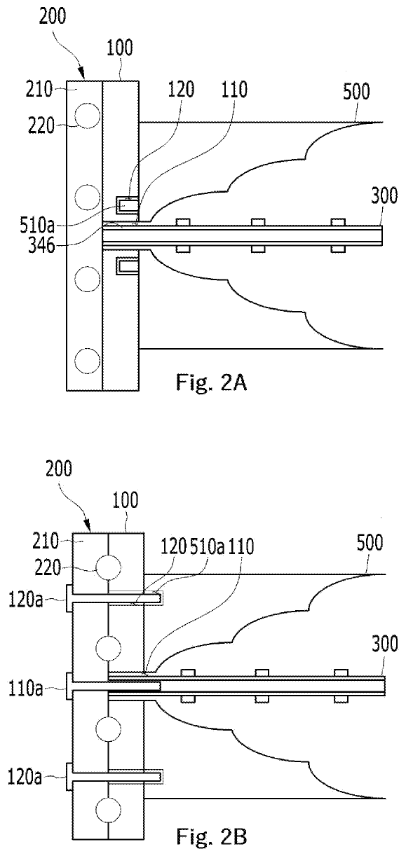

FIG. 1A is a schematic perspective view of a light radiation apparatus 10 for an exposure machine according to an embodiment of the present disclosure. FIG. 1B is a front view of the light emission apparatus 10 for an exposure machine according to an embodiment of the present disclosure. FIG. 2A is a cross-sectional view of the light emission apparatus 10 according to an embodiment of the present disclosure and FIG. 2B is a cross-sectional view of a light emission apparatus 10 according to another embodiment of the present disclosure.

Referring to FIG. 1A, the x-direction in which light is emitted by the light emission apparatus 10 for an exposure machine is defined as the front direction of the light emission apparatus 10, the y-direction is defined as the up direction of the light emission apparatus 10, and the z-direction is defined as the right direction of the light emission apparatus 10.

Referring to FIG. 1A, the light emission apparatus 10 for an exposure machine according to an embodiment of the present disclosure may include a supporter 100, a light emission unit 300, and a reflector 500.

The supporter 100 can individually support the light emission unit 300 and the reflector 500. A plurality of light emission units 300 may be installed in the supporter 100. A plurality of light reflectors 500 may be installed in the supporter 100.

Referring to FIG. 1B, a plurality of light emission units 300 and a plurality of reflectors 500 may be individually installed in one supporter 100. A plurality of light emission units 300 and a plurality of reflectors 500 may be installed in the supporter 100 to correspond to each other one to one. One light emission unit 300 may be installed in an installation surface 101 of the supporter 100 to be disposed in an internal space 520 of one reflector 500. A plurality of light emission units 300 and a plurality of reflectors 500 may be installed in the supporter 100 in rows and columns that are respectively arranged in parallel.

The supporter 100 may be made of a metal material or a plastic material having high strength to support the weight of the light emission unit 300 and the reflector 500.

The supporter 100 may be a solid having a plurality of surfaces. The supporter 100 may have an installation surface in which the light emission unit 300 and the reflector 500 are installed. The installation surface 101 may be formed in a polygonal shape such as a circle, an ellipse, a rectangle, a square, a right-angled tetragon, a pentagon, and a hexagon. The installation surface 101 may be a plane of a curved surface. When the installation surface is a curved surface, the installation surface 101 may be formed concavely to have a predetermined curvature.

The entire shape of the supporter 100 may be a plate shape having the installation surface 101. The entire shape of the supporter 100 may be a rectangular parallelepiped shape having the installation surface 101.

The front surface of the supporter 100 may be defined as the installation surface and the supporter 100 may have a rear surface 101 and sides (not shown) connecting the front surface and the rear surface 102.

Alternatively, a plurality of surfaces of the supporter 100 may be curved surfaces except for the installation surface 101 and the curved surfaces may be formed concavely or convexly rearward from the supporter 100.

The supporter 100 may include a first supporter fixer 110 to fix the light emission unit 300 in the installation surface 101. A plurality of first supporter fixers 110 may be provided to correspond to a plurality of light emission units 300 installed in the installation surface 101.

The supporter 100 may include a second supporter fixer 120 to fix the reflector 500 in the installation surface 101. A plurality of second supporter fixers 120 may be provided to correspond to a plurality of reflectors 500 installed in the installation surface 101.

Referring to FIG. 2A, the first supporter fixer 110 according to an embodiment may have a groove or hole shape in which a first end of the light emission unit 300 can be inserted. The first supporter fixer 110 may have a thread on the inner surface such that a thread formed on the outer surface of the first end of the light emission unit 300 can be separately coupled thereto. The light emission unit 300 can be thread-fastened to the first supporter fixer 110.

Referring to FIG. 2A, the second support fixer 120 according to an embodiment may have a groove or hole shape in which a portion of the reflector 500 can be inserted. The second supporter fixer 120 may have a thread on the inner surface such that a thread formed on the outer surface of a portion of the reflector 500 can be separately coupled thereto. The second supporter fixer 120 may have a coaxial circular or hole shape having a larger diameter than the first supporter fixer 110 (see FIG. 1A).

Referring to FIG. 2B, a first supporter fixer 110 according to another embodiment may have a hole shape through which a light emission unit-fixing bolt 110a passes without the first end of the light emission unit 300 inserted. Though not shown, the first supporter fixer 110 may have a groove shape in which the light emission unit-fixing bolt 110a can be inserted and fixed. The light emission unit-fixing bolt 110a protrudes further than the installation surface 101 of the supporter 100 and a thread of the light emission unit-fixing bolt 110a is inserted in the first end of the light emission unit 300, thereby being able to fix the light emission unit 300.

Referring to FIG. 2B, a second supporter fixer 120 according to another embodiment may have a hole shape through which a reflector-fixing bolt 120a passes. Though not shown, the second supporter fixer 120 may have a groove shape in which the reflector-fixing bolt 120a can be inserted and fixed. The reflector-fixing bolt 120a protrudes forward further than the installation surface 101 of the supporter 100 and a thread of the protruding reflector-fixing bolt 120a is inserted in a first end of the reflector 500, thereby being able to fix the reflector 500.

Though not shown, a first supporter fixer 110 according to another embodiment may be formed by combining those shown in FIGS. 2A and 2B. In detail, for example, the first supporter fixer 110 may have a hole shape in which the first end of the light emission unit 300 is partially inserted and that passes through the supporter 100 forward from the rear. A light emission unit-fixing bolt 110a passing through the first supporter fixer 110 having a hole shape can fix the light emission unit 300 while passing through the first end of the light emission unit 300.

Though not shown, a second supporter fixer 120 according to another embodiment may be formed by combining those shown in FIGS. 2A and 2B. In detail, for example, the second supporter fixer 120 may have a hole shape in which a first end of the reflector 500 is partially inserted and that passes through the supporter 100 forward from the rear. A reflector-fixing bolt 120a passing through the second supporter fixer 120 having a hole shape can fix the reflector 500 while passing through the first end of the reflector 500.

There was a problem in the related art that since a light emission unit and a reflector are integrated in a module, when any one of the light emission unit and the reflector is damaged, the entire module has to be replaced, the cost for replacement is large. As described above, since the light emission unit 300 and the reflector 500 are individually installed and fixed in the supporter 100 in the present disclosure, when one of the light emission unit 300 and the reflector 500 is replaced, they do not influence each other. For example, when the light emission unit 300 is damaged, repair is possible by replacing the light emission unit even without separating the reflector from the supporter 100. On the other hand, when the reflector 500 is damaged, repair is possible by replacing only the reflector 500 even without separating the light emission unit 300. Accordingly, the present disclosure can reduce the cost for replacing the light emission unit 300 or the reflector 500.

The body of the supporter 100 itself may be a cooling member. In this case, the supporter 100 may have a supporter body 100a made of a material having high thermal conductivity and a supporter cooling pipe 100b disposed through the supporter body 100a to pass a heat exchange fluid. The supporter body 100a may be made of a metal material and may be made of copper or aluminum having high thermal conductivity.

Accordingly, the supporter 100 can cool the light emission unit 300 and the reflector 500 combined with the supporter 100 by taking heat from the light emission unit 300 and the reflector 500.

The light emission apparatus 10 for an exposure machine according to an embodiment of the present disclosure may further include a supporter cooler 200.

Referring to FIGS. 1A and 2A, the supporter cooler 200 according to an embodiment of the present disclosure may be coupled to the rear surface of the supporter 100 to remove heat of the supporter 100. In this case, the supporter cooler 200, which is a part separate from the supporter 100, may be in surface contact with the rear surface of the supporter 100 to be coupled to the rear surface of the supporter 100 with the maximum surface area. The supporter cooler 200 may include a cooling body 210 that is a solid and a plurality of cooling pipes 220 disposed through the cooling body and passing a refrigerant therethrough. The supporter cooler 200 may include a plurality of cooling fins (not shown) and a plurality of cooling pipes 220 disposed through the cooling fins and passing a refrigerant therethrough.

Referring to FIG. 2B, a supporter cooler 200 according to another embodiment may be coupled to the rear surface of the supporter 100 to remove heat of the supporter 100. However, in this case, the supporter cooler 200 can implement the cooling function together with the supporter 100. The supporter cooler 200 may include a cooling body 210 being in surface contact with the rear surface of the supporter 100 with the maximum surface area, and a plurality of cooling pipes 220 disposed through the cooling body 210 and the supporter in parallel with the contact surfaces of the cooling body 210 and the supporter 100 to be in surface contact with the cooling body 210 and the supporter 100, and passing a refrigerant therethrough.

The refrigerant may be any substance as long as it is a fluid that can take heat from the supporter cooler 200, and water may be used in the present disclosure.

Since the supporter 100 is individually combined with a plurality of light emission units 300 and a plurality of reflectors 500, the supporter 500 intactly receives heat generated by the light emission units 300 and the reflectors 500. Since the heat of the supporter 100 is removed by the supporter cooler 200, it is possible to prevent the supporter 100 from being thermally damaged by excessive heat.

The supporter cooler 200 is made of a material having higher heat transfer efficiency than the supporter 100, so the heat of the supporter 100 can efficiently transfer to the supporter cooler 200. The supporter cooler 200 may be made of a metal material having high heat transfer efficiency. Hereafter, the reflector 500 of the present disclosure is described.

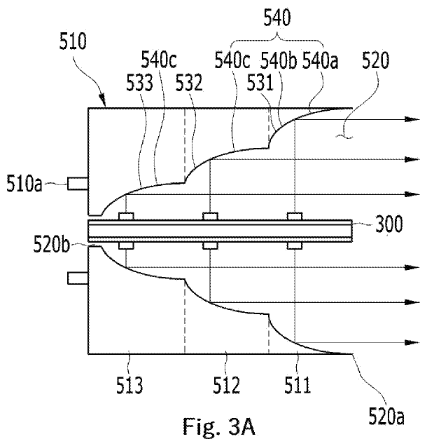

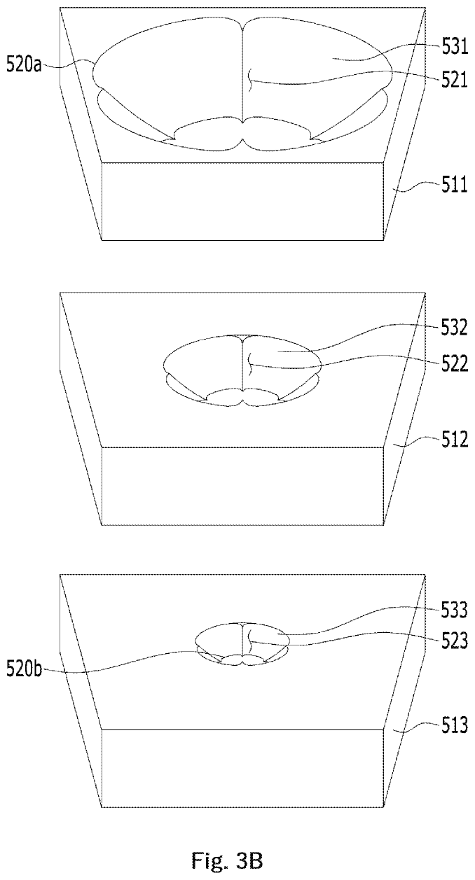

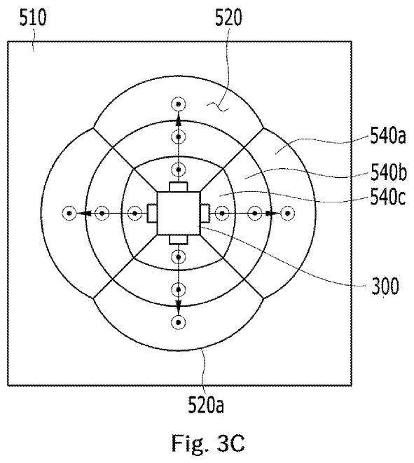

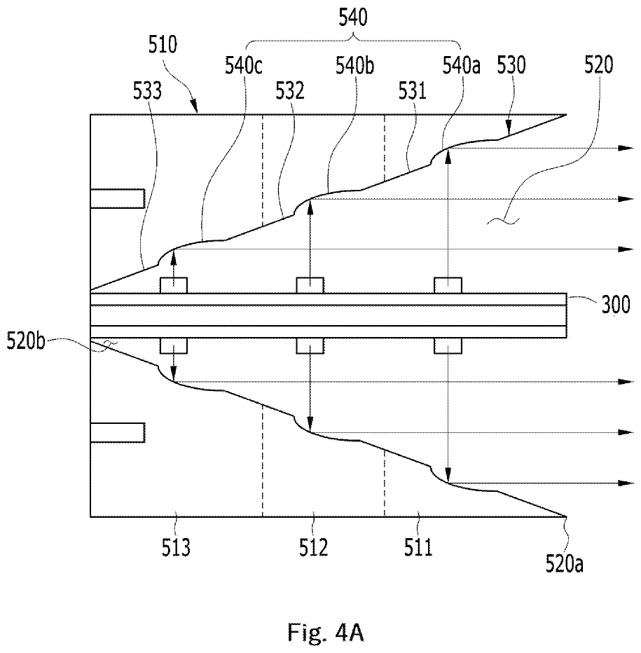

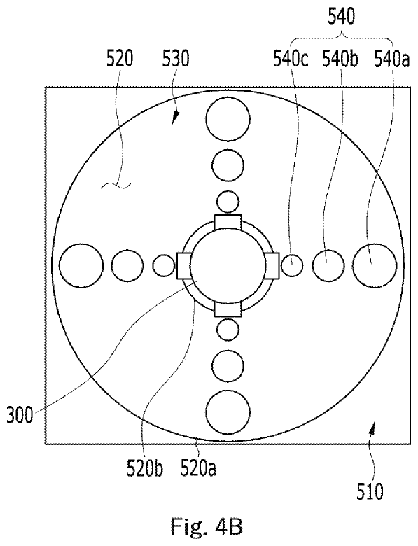

FIGS. 3A and 3B are a cross-sectional view and an exploded perspective view of a reflector 500 according to an embodiment. FIGS. 4A and 4B are a cross-sectional view and a plan view of a reflector 500 according to another embodiment.

Referring to FIGS. 3A and 4A, a reflector 500 according to an embodiment may have a reflector body 510, an internal space formed inside the reflector body 510 to dispose a light emission unit 300 therein, and an internal surface 530 having a plurality of reflective surfaces 540 that reflects the light generated by the light emission unit 300.

The reflector body 510 may be made of a metal material having high thermal conductive efficiency. However, since the reflector body 510 has to reflect light too, it may be made of aluminum that is a metal material having not only high thermal conductive efficiency, but high light reflectivity.

The reflector body 510 may have a reflector body fixer 510a on the rear surface that can be coupled to the second supporter fixer 120. A reflector body fixer 510a according to an example protrudes rearward and can be inserted in the second supporter fixer 120 (see FIG. 2A) and a reflector body fixer 510a according to another example is formed in a hole or groove shape and can be inserted and fixed by the reflector-fixing bolt 120a passing through the second supporter fixer 120 (see FIG. 2B).

The reflector body fixer 510a may have a front opening 520a that is open forward and a rear opening 520b that is open rearward. The front opening 520a may have an area larger than that of the rear opening 520b. The front opening 520a and the rear opening 520b may be formed in circular shapes. The front opening 520a functions as an opening for emitted light of the reflector 500 when light generated by the light emission unit 300 is reflected outside by the reflective surfaces 540. The rear opening 520b functions as an opening through which the light emission unit 300 passes and in which a first end of the light emission unit can be directly installed in the supporter 100.

The outer shape of the reflector body 510 may have a rectangular parallelepiped shape, but is not limited thereto and may have shapes such as a circular cylinder, a triangular prism, a square prism, a pentagonal prism, a hexagonal prism, and an inverse cone.

The entire reflector body 510 may be one integral body or may be formed by assembling a plurality of reflector pieces 511, 512, and 513, as shown in FIG. 3B.

The reflector pieces 511, 512, and 513 may include a first reflector piece 511 having the front opening 520a, a second reflector piece 512 coupled to the rear of the first reflector piece 511, and a third reflector piece 513 coupled to the rear of the second reflector piece 512 and having the rear opening 520b. However, three reflector pieces are exemplified in an embodiment of the present disclosure, but it is only an example, and the number of the reflector pieces may be changed into two, four, five, six, etc., depending on the number of light emitter spots of the light emission unit 300 or the required amount of light.

The reflector pieces 511, 512, and 513 are combined with each other, whereby one reflector body 510 can be formed. The reflector pieces 511, 512, and 513 each may have a shape obtained by vertically cutting the reflector body 510 in the front-rear direction with a predetermined length.

The internal space 520 can provide a space in which the light emission unit is disposed. The internal space 520 refers to the space defined inside the reflector body 510 by the internal surface 530.

The internal space 520 is open forward and rearward by the front opening 520a and the rear opening 520b. The vertical cross-sectional area of the internal space 520 decreases as it goes forward, whereby the internal space 520 does not interfere with the paths of the reflective beams reflected by the reflective surfaces 540 to be described below. The internal surface 530 of the internal space 520 may be inclined close to the light emission unit 300 as it goes rearward.

The internal space 520 may include a first internal space 521 defined by the first reflector piece 511, a second internal space 522 defined by the second reflector piece 512, and a third internal space 523 defined by the third reflector piece 513. However, the internal space may be further divided, depending on the number of the reflector pieces. For example, a fourth internal space, a fifth internal space, etc. may be further defined.

The first internal space 521 communicates forward with the front opening 520a and communicates rearward with the second internal space 522. The third internal space 523 communicates rearward with the rear opening 520b and communicates forward with the second internal space 522. The front opening of the second internal space 522 may have a shape corresponding to the rear opening of the first internal space 521, and the rear opening of the second internal space 522 may have a shape corresponding to the front opening of the third internal space 523.

The internal surface 530, which is a surface formed inside the reflector body 510, defines the internal space 520.

The internal surface 530 may include a first internal surface 531 that is the inner surface of the first internal space 521, a second internal surface 532 that is the inner surface of the second internal space 522, and a third internal surface 533 that is the inner surface of the third internal space 523. However, the internal surface may be further divided, depending on the number of the reflector pieces. For example, a fourth internal surface, a fifth internal surface, etc. may be further formed.

The internal surface 530 may have a shape rotated about a central axis 01 in the longitudinal direction of the light emission unit 300. For example, the internal surface 530 may have a circular shape rotated 360 degrees about the central axis 01. Alternatively, the internal surface 530 may have an arc shape rotated a predetermined angle about the central axis 01 or may have a shape obtained by combining a plurality of arcs. The internal surface 530 may have a cross-section having a circular shape or a shape obtained by overlapping a plurality of arcs with respect to a perpendicular direction of the light emission unit 300. FIG. 3B shows an example of the internal surface 530 having a shape obtained by combining four arcs and the number of arcs may depend on the number of the light emitter spots of the light emission unit 300.

The internal surface 530 may have a plurality of reflective surfaces 540 that reflects the light from the light emission unit 300. The reflective surfaces 540 may be formed on the surface of the internal surface 530.

As shown in FIG. 3A, the reflective surfaces 540 according to an embodiment may be formed throughout the internal surface 530. In other words, it is possible to reflect light using the entire internal surface 530 be forming the entire surface of the internal surface 530 as the reflective surfaces 540. In this case, a first reflective surface 540a may be formed on the entire first internal surface 531, a second reflective surface 540b may be formed on the entire second internal surface 532, and a third reflective surface 540c may be formed on the entire third internal surface 533.

Referring to FIG. 4A, a plurality of reflective surfaces 540 according to another embodiment may be formed at a portion of the internal surface 530. The reflective surfaces 540 may be formed on the internal surface 530 corresponding to positions having the light emitter spots of the light emission unit 300 as focuses in the longitudinal direction of the light emission unit 300. In this case, a first reflective surface 540a may be partially formed on the first internal surface 531, a second reflective surface 540b may be partially formed on the second internal surface 532, and a third reflective surface 540c may be partially formed on the third internal surface 533 in the longitudinal direction of the light emission unit 300.

Referring to FIG. 4B, the reflective surfaces 540 may be formed on the internal surface 530 corresponding to positions having the light emitter spots of the light emission unit 300 as focuses with respect to the central axis 01 in the longitudinal direction of the light emission unit 300. In this case, a first reflective surface 540a may be partially formed on the first internal surface 531, a second reflective surface 540b may be partially formed on the second internal surface 532, and a third reflective surface 540c may be partially formed on the third internal surface 533 around the central axis 01 of the light emission unit 300.

According to the present disclosure, it is possible to reduce the cost for curving the entire internal surface by forming reflective surfaces 540a to 540c by machining only portions of the first to third internal surfaces 531 to 533 in the longitudinal direction or circumferential direction of the light emission unit 300.

The reflective surfaces 540 may be formed by coating the internal surface 530 with a substance having high reflectivity or by polishing the internal surface 530 to increase reflectivity. Alternatively, the reflective surfaces 540 may be detachably coupled to the reflector body 510.

The reflective surfaces 540 may be formed as any one of elliptical surfaces, parabolic surfaces, and free curve surfaces with respect to the longitudinal direction of the light emission unit 500.

When a light emitter spot of the light emission unit 300 is a first focus of an ellipse, it is possible to achieve an effect that the reflected beam reflected by an elliptical reflective surface is concentrated to a second focus of the ellipse. When a light emitter spot of the light emission unit 300 is the focus of a parabola, the reflective beam reflected by one parabolic reflective surface can make parallel horizontal beams. An inclined beam that is inclined in the longitudinal direction of the light emission unit can be obtained from the reflected beam reflected by one same free curve surface, depending on the design of the reflective surface of the free curve surface.

Referring to FIGS. 3A to 4B, a plurality of reflective surfaces 540 of the reflector 500 is a plurality of parabolic reflective surfaces, in which the parabolic reflective surfaces respectively have light emitter spots of the light emission unit 300 and the reflective beams reflected by the parabolic reflective surfaces are all formed in parallel in the longitudinal direction of the light emission unit 300.

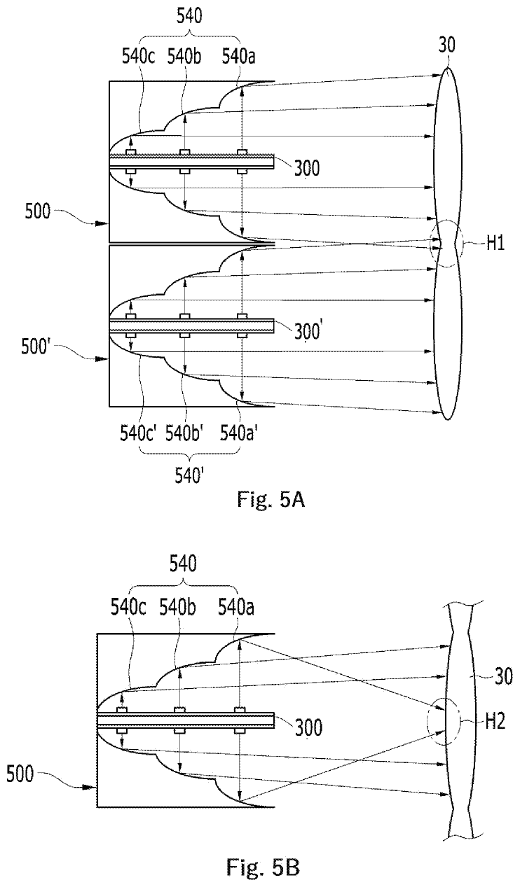

FIGS. 5A and 5B are cross-sectional views of a reflector according to another embodiment.

Referring to FIGS. 5A and 5B, a reflector 500 can form an inclined beam that is inclined not to be parallel with the longitudinal direction from the reflected beam reflected by at least one reflective surface of a plurality of reflective surfaces 540. At least one of the reflective surfaces 543 of the reflector 500 may be any one of an elliptical surface, a parabolic surface, and a free curve surface.

Referring to FIG. 5A, when all reflective beams reflected by one reflector 500 are parallel horizontal beams, the amount of light passing through the groove of a beam uniformer 30 becomes insufficient due to a physical shade section that may be generated between the reflected beam from the first reflector 500 and the reflected beam from the adjacent second reflector 500′, so there may be a problem of non-uniform illumination of a lattice shape in the irradiation region 80.

In order to solve this problem, according to the present disclosure, the reflected beam from at least one of a plurality of reflective surfaces 540 of the first reflector 500 may overlap the reflected beam from at least one of a plurality of reflective surfaces 540′ of the second reflector 500′ when traveling into the beam uniformer 30. In detail, the reflected beam from the first reflective surface 540a of the first reflector 500 and the reflected beam from the first reflective surface 540a′ of the second reflector 500′ may be inclined to overlap each other, and the region H1 where two reflected beams overlap may be defined as the groove of the beam uniformer 30.

Referring to FIG. 5B, when all beams reflected by one reflector 500 are parallel horizontal beams, a physical shade section may be generated in the direction of the central axis 01 of the light emission unit 300 disposed at the center of the reflector 500 because there is no light source at the front end of the light emission unit 300.

In order to solve this problem, a light source may be disposed at the front end of the light emission unit 300, but the light from the light source disposed at the front end of the light emission unit 300 directly reaches the beam uniformer 300 without being reflected by the reflector 500, so non-uniform illumination of a spot shape may be caused by an excessive amount of light in the irradiation region. Accordingly, in the present disclosure, it is possible to guide the reflective beam from at least one reflective surface of the reflective surfaces 540 of the reflector to the region H2 where the central axis 01 of the light emission unit 300 and the beam uniformer 300 meet each other. In detail, by inclining the reflective beam from the first reflective surface 540a of the reflector 500 toward the central axis 01 of the light emission unit 300, the reflective beam can reach the region H2 where the beam uniformer 30 and the central axis 01 meet each other.

In FIGS. 3A to 5B, the reflective beams reflected by the reflector 500 may be formed symmetrically to each other with respect to the central axis 01 of the light emission unit 300.

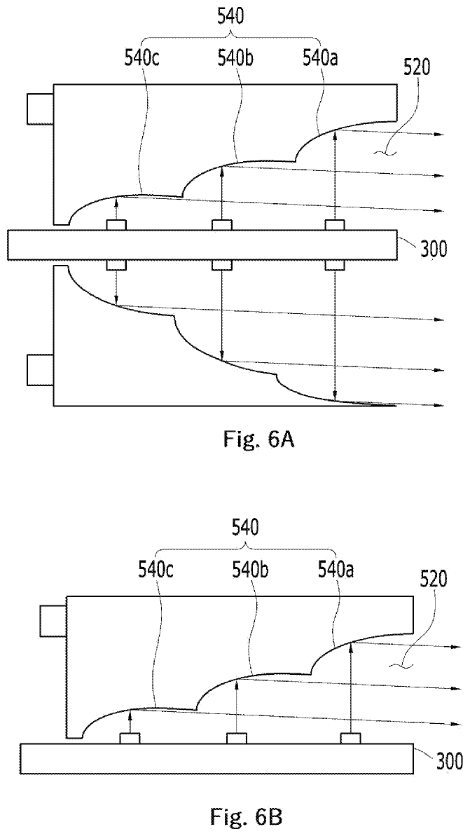

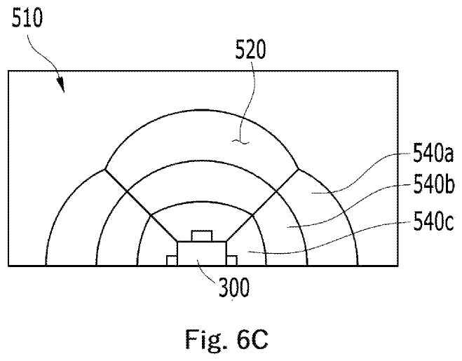

FIGS. 6A, 6B, and 6C are cross-sectional views of a reflector according to another embodiment.

In FIGS. 6A to 6B, the reflective beams reflected by the reflector 500 may be formed not symmetrically to each other with respect to the central axis 01 of the light emission unit 300.

Referring to FIG. 6A, the reflective beams reflected by the reflector 500 are inclined beams inclined with respect to the central axis 01 of the light emission unit 300. Reflective beams reflected by one reflector 500 may be parallel beams, or, not shown though, may not be parallel beams. In order to form a beam inclined with respect to the central axis 01 of the light emission unit 300, it is possible to generate an inclined beam by applying at least one of an elliptical surface, a parabolic surface, and a free curve surface to a plurality of reflective surfaces 540 of the reflector 500. Referring to FIGS. 6B and 6C, the reflector 500 may be formed only at predetermined angles rather than 360 degrees, as shown in FIG. 6A, around the central axis 01 of the light emission unit 300. Referring to FIGS. 6B and 6C, the reflector 500 is formed only within 180 degrees around the central axis 01 of the light emission unit 300 and the internal space 520 of the reflector 500 may be open up or down to the outside.

Referring to FIG. 1B again, the light emission apparatus 100 for an exposure machine according to an embodiment of the present disclosure may include a plurality of reflectors 500.

The reflectors 500 may include a first reflective group P disposed close to ends of the supporter 100 and a second reflective group C disposed closer to the center of the supporter 100 than the first reflective group P

The first reflective group P may include a plurality of reflectors 500 installed in at least one row or column close to the upper end, the lower end, the left end, and the right end of the supporter 100. The second reflective group C may include a plurality of reflectors 500 except for the first reflective group P of the reflectors 500 installed in the supporter 100, that is, may include a plurality of reflectors 500 installed not close to the upper end, the lower end, the left end, and the right end of the supporter 100.

The second reflective group P is positioned at the center portion of the installation surface 101 of the supporter 100 and the first reflective group P is positioned close to edges of the installation surface 101 of the supporter 100. The first reflective group C is positioned further outside the center portion on the installation surface 101 of the supporter 100 than the second reflective group P.

The reference axes of the reflective beams reflected by the reflectors of the first reflective group P may be inclined like inclined beams and the reference axes of the reflective beams reflected by the reflectors of the second reflective group C may be horizontal like horizontal beams. A beam that is parallel with the longitudinal direction of the light emission unit 300 may be referred as a horizontal beam and a beam that is inclined with respect to the longitudinal direction may be referred to as an inclined beam.

The direction of the reference axis of a reflector is the average direction of the direction of the axes of a plurality of reflective beams reflected by a plurality of reflective surfaces of one reflector. Even though the reference axes of reflective beams from a reflector are horizontal, some of the reflective beams may be inclined beams, but the inclined beams are symmetrically inclined with respect to the light emission unit, they may have horizontal reference axes. On the other hand, even though the reference axes of the reflective beams from a reflector are inclined, some of the reflective beams may be horizontal beams, but the average direction of all the reflective beams may be inclined with respect to the light emission unit 300.

The reflective beams reflected by one reflector of the reflectors of the first reflective group P, as shown in FIGS. 6A and 6B, may be inclined beams that are not symmetric with respect to the light emission unit 300. The reflective beams from the first reflective group P may be inclined beams that can travel into an aperture 20 to be described below. Accordingly, the amount of light that does not pass through the aperture 20 is reduced, whereby it is possible to solve the problem of insufficient light in the irradiation region 80 that is generated when light does not reach the irradiation region 80. Alternatively, the ratio of inclined beams in the reflective beams from the first reflective group P may be larger than the ratio of parallel beams that are parallel with the longitudinal direction of the light emission unit 300.

The reflective beams reflected by one reflector of the reflectors of the second reflective group C, as shown in FIGS. 3A to 5B, may be beams that are symmetric with respect to the light emission unit 300. The reflective beams from the second reflective group C may be parallel beams. Alternatively, the ratio of inclined beams in the reflective beams from the second reflective group C may be smaller than the ratio of parallel beams that are parallel with the longitudinal direction of the light emission unit 300.

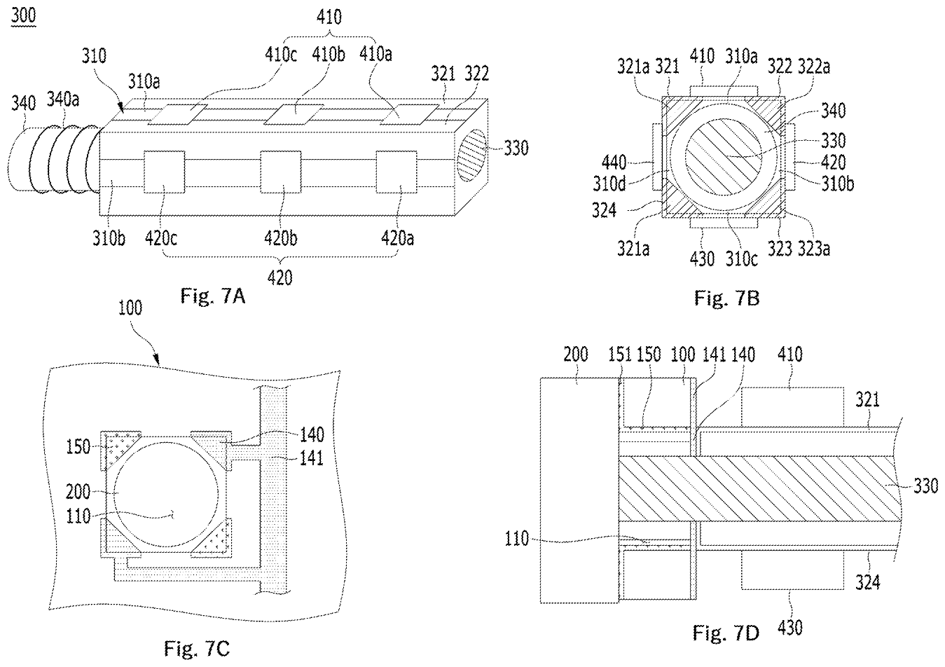

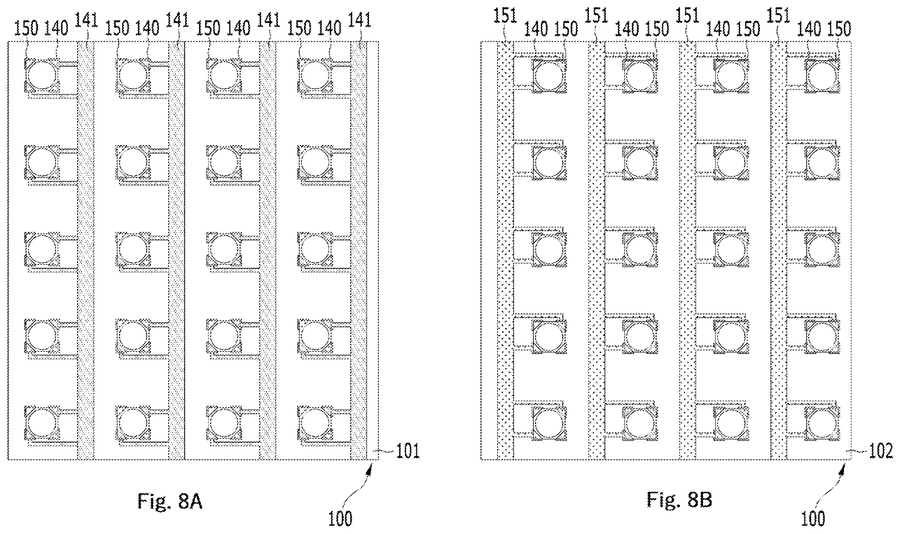

FIG. 7A is a perspective view of a light emission unit. FIG. 7B is a rear view of the light emission unit 300 seen from the rear. FIG. 7C is a view showing the structure in which the first supporter fixer 110 of the supporter 100 is formed in a hole shape. FIG. 7D is a cross-sectional view in which the light emission unit 300 is coupled to the first supporter fixer 110 of the supporter 100. FIG. 8A is a front view of the supporter and FIG. 8B is a rear view of the supporter.

Referring to FIG. 7A, the light emission unit 300 is a part that is installed in the supporter 100 and generates light toward reflective surfaces 540. As described above, a plurality of light emission units 300 may be detachably installed in rows and columns in one supporter 100.

The light emission unit 300 may include a plurality of light emitters 410, 420, 430, and 440 and a light emission unit body 310 on which the light emitters 410, 420, 430, and 440 can be mounted.

The light emission unit body 310 may be polyhedron having a plurality of mounting surfaces 310a, 310b, 310c, and 310d. The cross-section of the light emission unit body 310 may be a polygon such as a triangle, a rectangle, a pentagon, and a hexagon and the outer surface of the light emission unit body 310 may be composed of a plurality of rectangles. The number of the rectangles depends on the cross-sectional shape of the light emission unit body 310.

The light emission unit body 310 may have a column shape elongated in a direction (front-rear direction) may have a polyprism shape such as a triangular prism, a square prism, a pentagonal prism, and a hexagonal prism. FIG. 7A shows an example in which the light emission unit body 310 is a square prism.

The mounting surfaces 310a, 310b, 310c, and 310d may be formed in the rectangular shapes the form the outer surface of the light emission unit body 310. A plurality of light emitters 410, 420, 430, and 440 may be respectively mounted on the mounting surfaces 310a, 310b, 310c, and 310d forming the outer surface of the light emission unit body 310.

A plurality of light emitters 410a, 410b, and 410c may be mounted on one mounting surface 310a, a plurality of light emitters 420a, 420b, and 420c may be mounted on one mounting surface 310b, a plurality of light emitters 430a, 430b, and 430c may be mounted on one mounting surface 310c, and a plurality of light emitters 440a, 440b, and 440c may be mounted on one mounting surface 310d.

In other words, a plurality of light emitters may be mounted on one mounting surface of a light emitter in the longitudinal direction of the light emission unit body 310 and a plurality of light emitters may be mounted on a plurality of mounting surfaces circumferentially on the outer surface of the light emission unit body 310.

The light emission unit 300 may have a light emission unit fixer 340 that can be detachably coupled and fixed to the first supporter fixer 110. The light emission unit fixer 340 extends from an end of the light emission unit body 310 and may be inserted in a groove or a hole of the first supporter fixer 110. In this case, a thread may be formed on the outer surface of the light emission unit fixer 340. Alternatively, the light emission unit fixer 340 may be formed in a groove or hole shape in one end of the light emission unit body 310 and may be inserted and fixed by the light emission unit-fixing bolt 120a passing through the supporter 100.

Referring to FIG. 7B, the light emission unit 300 may include plus wires 321 and 323 and minus wires 322 and 324 on the mounting surfaces 310a, 310b, 310c, and 310d to supply electricity to the light emitters 410, 420, 430, and 440.

For example, the plus wire 321 and the minus wire 322 may be disposed on one mounting surface 310a and may be attached to the mounting surface 310a by an adhesive or may be formed by coating the mounting surface 310a with a metal substance. The light emitter 410 is electrically connected to the plus wire 321 and the minus wire 322 on one mounting surface 310a and is supplied with power, thereby being able to generate light.

The plus wires 321 disposed on adjacent two mounting surfaces 310a and 310d may be formed as one electrically connected member and the minus wires 322 mounted on adjacent two mounting surfaces 310a and 310b may be formed as one electrically connected member. Accordingly, when the light emission unit body 310 is a square prism, adjacent mounting surfaces share plus wires or minus wires at the edges of the square, and it is possible to supply electricity to light emitters mounted on four mounting surfaces using only two plus wires and two minus wires.

If the light emission unit body 310 is a hexagonal prism, it is possible to supply electricity to light emitters mounted on each mounting surface using three plus wires and three minus wires mounted on two mounting surfaces adjacent to each of the edges of the hexahedron.

Referring to FIG. 7C, the supporter 100 may include a plus connection line 140 disposed on the supporter 100 electrically in contact with the plus wires 321 and 323 of the light emission unit 300 and a minus connection line 150 disposed on the supporter 100 electrically in contact with the minus wires 322 and 324 of the light emission unit 300.

Referring to FIG. 7D, the plus connection line 140 and the minus connection line 150 may be formed on the installation surface 101 of the supporter 100 and may be respectively electrically in contact with the plus wires 321 and 323 and the minus wires 322 and 324 extending to the rear surface of the light emission unit body 310.

Referring to FIGS. 8A and 8B, the plus connection line 140 may be electrically connected to a plus extension line 141 formed on the installation surface 101 of the supporter 100 and the minus connection line 150 may be electrically connected to a minus extension line 151 formed on the rear surface of the supporter 100. The plus extension line 141 and the minus extension line 151 are connected to an external terminal, so they can be supplied with electricity. The arrangement of the plus terminal and the minus terminal described above is only an example without limiting the present disclosure and may be switched.

Referring to FIGS. 7A to 7D, the light emitters 410, 420, 430, and 440, which are parts or elements that generate light when electricity is applied, may be one of an LED chip or an LED package. The light emitters 410, 420, 430, and 440 may be mounted on the mounting surfaces 310a, 310b, 310c, and 310d.

Hereafter, the relationship of a plurality of light emitters mounted in the longitudinal direction of the light emission unit 300 is described. For example, a plurality of light emitters 410a, 410b, and 410c mounted in the longitudinal direction of the light emission unit 300 may include a first light emitter 410a, a second light emitter 410b, and a third light emitter 410c sequentially disposed rearward from the front end of the light emission unit 300.

The light emitters 410a, 410b, and 410c may be disposed on one mounting surface 310a, 310b, 310c, 310d with predetermined gaps therebetween in the longitudinal direction of the light emission unit 300. In this case, the number of light emitters installed on each mounting surface may be the same for all mounting surfaces.

The light emitters 410a, 410b, and 410c may be disposed on a plurality of mounting surfaces with predetermined gaps therebetween in the circumferential direction of the light emission unit 300. In this case, the number of the light emitters circumferentially installed at a first position in the longitudinal direction of the light emission unit 300 may be the same as the number of the light emitters circumferentially installed at a second position in the longitudinal direction.

The light emitters 410, 420, 430, and 440 may have the same beam profile. The optical axes of the light emitters 410, 420, 430, and 440 may be positioned in the normal directions of the mounting surfaces 310a, 310b, 310c, and 310d on which the light emitters are respectively installed.

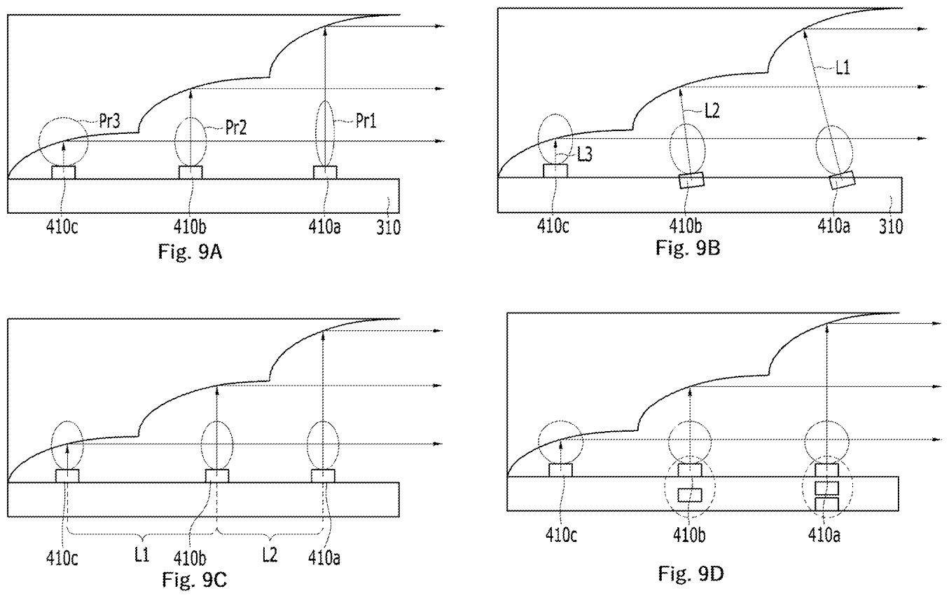

FIG. 9A is a view showing the beam profiles of a plurality of light emitters installed on one installation surface. FIG. 9B is a view showing the optical axes of a plurality of light emitters installed on one installation surface. FIG. 9C is a view showing the distances between a plurality of light emitters installed on one installation surface. FIG. 9D is a view showing the number of a plurality of light emitters installed on one installation surface.

When a plurality of light emitters 410a, 410b, and 410c is mounted on the light emission unit body 310 in the longitudinal direction of the light emission unit 300 and all the light emitters 410a, 410b, and 410c are disposed in the internal space 520 of the reflector 500, the beams generated by the first light emitter 410a installed at the front end of the light emission unit body 310 are not all reflected by the reflective surface 540a and some of the beams may become dead beams. This may cause a lack of amount of light traveling into the beam uniformer 30. Hereafter, a method of solving the problem of an insufficient amount of light traveling into the beam uniformer 30 is described with reference to FIGS. 9A to 9D.

Referring to FIG. 9A, at least one of the light emitters 410a, 410b, and 410c installed in the longitudinal direction of the light emission unit 300 may have a different beam profile. The light emitters 410a, 410b, and 410c may be installed such that the directional angles of the beam profiles thereof decrease as they go to the front of the light emission unit 300. The directional angle of a beam profile refers to the region that actually influences the irradiation region 80 in the distribution of light generated by a light emitter and the range of light is expressed in ‘degrees’. The directional angle is defined as two times (corresponding to the left and the right when seen from the front) the angle until the output of a beam profile becomes 50% of the maximum peak.

Accordingly, the directional angle of the beam profile of the light emitter 410a installed at the front end of the light emission unit 300 is set smaller than those of the rear light emitters 410b and 410c, whereby all the beams generated by the light emitter 410a are reflected by the reflective surface 540a and reach the beam uniformer 30 and the problem of an insufficient amount of light can be solved.

Referring to FIG. 9B, at least one of the light emitters 410a, 410b, and 410c installed in the longitudinal direction of the light emitter 300 may have a different optical axis direction. The light emitters 410a, 410b, and 410c may be installed such that the optical axis directions are inclined rearward as they go to the front of the light emission unit 300. For example, the light emitter 410c may have an optical axis perpendicular to the longitudinal direction of the light emission unit 300, the light emitter 410b may have an optical axis of 80 degrees, and the light emitter 410a may have an optical axis of 70 degrees.

In order to make the optical axes of the light emitters 410a, 410b, and 410c different, the light emitters 410a, 410b, and 410c may be the same light emitters but may be installed at an angle. Alternatively, the light emitters 410a, 410b, and 410c may not be the same light emitters and light may be emitted from the light emitters with optical axes having different inclinations.

Accordingly, the optical axis of the light emitter 410a installed at the front end of the light emission unit 300 is inclined rearward, whereby all of beams corresponding to the directional angle of the beam profile of the light emitter 410a can be reflected by the reflective surface 540a and can reach the beam uniformer 30.

Referring to FIG. 9C, the light emitters 410a, 410b, and 410c installed in the longitudinal direction of the light emitter 300 may be installed on the light emission unit body 310 with different gaps therebetween. The gaps between the light emitters 410a, 410b, and 410c may decrease as they go to the front of the light emission unit 300. For example, the distance L2 between the first light emitter 410a and the second light emitter 410b may be shorter than the distance L1 between the second light emitter 410b and the third light emitter 410c.

Accordingly, by making the density of the light emitter installed at the front end of the light emission unit 300 larger than that at the rear of the light emission unit 300, it is possible to compensate for the amount of dead beams not reflected by the front reflective surface 410a and it is possible to efficiently circulate the heat generated by the light emitters using the front portion wider than the rear portion of the internal space 520.

Referring to FIG. 9D, the number of a plurality of light emitters installed in the circumferential direction of the light emitter 300 may be changed, depending on the positions in the longitudinal direction of the light emission unit. The number of a plurality of light emitters may be increased toward the front of the light emission unit 300. For example, the number of light emitters installed on the circumference of the light emission unit 300 on which the first light emitter 410a is installed may be larger than the number of light emitters installed on the circumference of the light emission unit 300 on which the second light emitter 410b is installed.

Accordingly, by making the number of the light emitter installed at the front end of the light emission unit 300 larger than that at the rear of the light emission unit 300, it is possible to compensate for the amount of dead beams not reflected by the front reflective surface 410a and it is possible to efficiently circulate the heat generated by the light emitters using the front portion wider than the rear portion of the internal space 520.

The light emission unit 300 may include a light emission unit cooler 330 in the light emission unit body 310 and the light emission unit cooler 330 may be in contact with the supporter cooler 200 and can transmit the heat generated by light emitters to the supporter cooler 200.

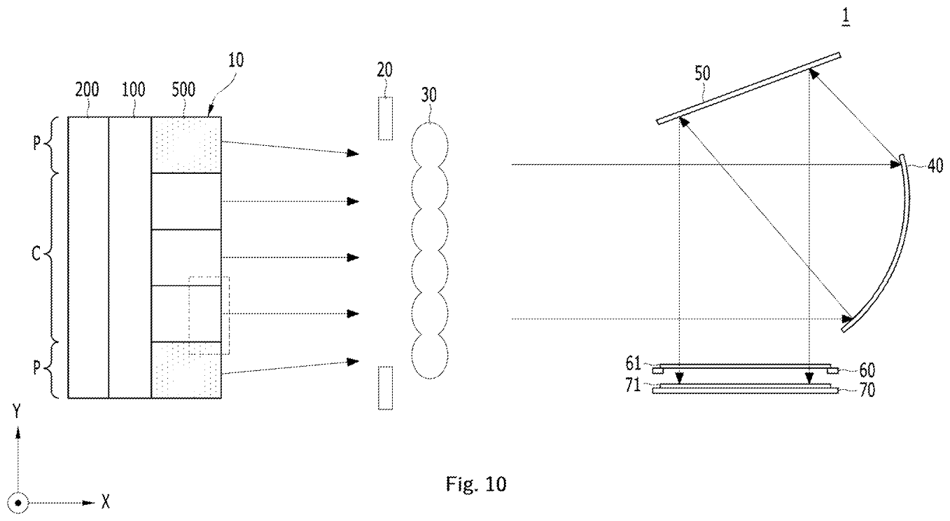

FIG. 10 is a view showing the configuration of exposure equipment 1 using the light emission apparatus 10 for an exposure machine.

Referring to FIG. 10, exposure equipment 1 according to an embodiment of the present disclosure may include a light emission apparatus 10 for an exposure machine, an aperture 20, a beam uniformer 30, a concave mirror 40, a plane mirror 50, a mask stage 60, and an object stage 70.

The light emission apparatus 10 for an exposure machine may be configured by combining all the components described above.

The aperture has an opening smaller in size than the beam uniformer 30 and is disposed ahead of the beam uniformer 30 in a light path to remove unnecessary beams of beams emitted from the light emission apparatus 10 for an exposure machine.

The beam uniformer 30 may be one of a fly eye lens (FEL), a rod lens, and an integrator lens. The beam uniformer 30 is a lens that uniforms all the beams that has passed through the aperture 20, and then sends out the beams.

The concave mirror 40 is an optical part for removing beams except for parallel beams of the beams traveling out of the beam uniformer 30. Beams traveling to the concave mirror 40 do not reach the plane mirror 50 except for beams that are reflected by the concave mirror 40 toward the plane mirror 50 and the beams not reaching the plane mirror 50 do not reach the irradiation region 80 as inclined beams rather than parallel beams. Accordingly, only parallel beams that are parallel with the normal direction of the irradiation region 80 reach the irradiation region 80.

The reflective mirror 50 is an optical part that changes the path of light reflected by the concave mirror 40 to the irradiation region 80.

A mask 61 may be placed on the mask stage 60 and the mask stage 60 can be moved not only in the planes of the X-axis and the Z-axis, but also in the Y-axial direction by a mask actuator (not shown).

An object 71 may be placed on the object stage 70 and the object stage 70 can be moved not only in the planes of the X-axis and the Z-axis, but also in the Y-axial direction by a wafer actuator (not shown).

Light reflected by the reflective mirror 50 passes through the mask 61 on the mask stage and the light that has passed through the mask 61 reaches the object 71, thereby forming the irradiation region 80 on the object 71. The object 71 may be one of a semiconductor device, a printed substrate, and a liquid crystal display panel.

By using the configuration of the light emission apparatus 10 for an exposure machine according to an embodiment of the present disclosure and another exposure equipment 1, beams that reach the irradiation region 80 can almost perpendicularly travel to the object 71 and the incident beams may be parallel with each other.

Although the present disclosure has been described with reference to the exemplary embodiments illustrated in the drawings, those are only examples and may be changed and modified into other equivalent exemplary embodiments from the present disclosure by those skilled in the art. Therefore, the technical protective range of the present disclosure should be determined by the scope described in claims.

What is claimed is:

1. A light emission apparatus for an exposure machine, comprising:
a supporter;
a plurality of light emission units individually installed on a first surface of the supporter and each having a plurality of light emitters generating light on an outer surface thereof; and
a plurality of reflectors individually installed on the first surface of the supporter to correspond to the light emission units, respectively,
wherein the reflectors are divided into a first reflective group in which reference axes of reflective beams are inclined and a second reflective group in which reference axes of reflective beams are horizontal.

2. The light emission apparatus of claim 1, wherein the first reflective group is positioned further outside a center portion on the first surface of the supporter than the second reflective group.

3. The light emission apparatus of claim 1, wherein a direction of the reference axis of a reflective beam is an average of directions of optical axes of reflective beams reflected by one reflector.

4. The light emission apparatus of claim 1, wherein the light emission units and the reflectors are each individually detachably coupled to the supporter.

5. The light emission apparatus of claim 1, wherein the reflectors each have:
a plurality of reflective surfaces reflecting light in correspondence to each of the light emitters installed on one of the light emission units; and
a reflector body integrally or detachably having the reflective surfaces.

6. The light emission apparatus of claim 5, wherein the reflective surfaces are at least one of parabolic surfaces, elliptical surfaces, or free curve surfaces.

7. The light emission apparatus of claim 1, wherein the supporter itself is a water-cooling member or the supporter is cooled by a supporter cooler attached to a rear surface of the supporter.

8. An exposure equipment including a light emission apparatus, comprising:
a light emission apparatus generating beams;
an aperture removing unnecessary beams from the beams;
a beam uniformer uniforming the beams;
at least one mirror making beams that have passed through the beam uniformer into parallel beams;
a mask stage supporting a mask that transmits the parallel beams; and
an object stage supporting an object to which beams that have passed through the mask reach,
wherein the light emission apparatus includes:
a supporter;
a plurality of light emission units individually installed on a first surface of the supporter and each having a plurality of light emitters generating light on an outer surface thereof; and
a plurality of reflectors individually installed on the first surface of the supporter to correspond to the light emission units, respectively,
wherein the reflectors are divided into a first reflective group in which reference axes of reflective beams are inclined and a second reflective group in which reference axes of reflective beams are horizontal.
